(19) United States
(12) Patent Application Publication
(10) Pub. No.: US 2009/0098668 A1
(43) Pub. Date: Apr. 16, 2009

(54) Method and Apparatus to Facilitate Testing of Printed Semiconductor Devices

(75) Inventors: Paul W. Brazis, South Elgin, IL (US); Daniel R. Gamota, Palatine, IL (US); Krishna Kalyanasundaram, Elmhurst, IL (US); Jie Zhang, Buffalo Grove, IL (US); Krishna D. Jonnalagadda, Algonquin, IL (US)

Correspondence Address: MOTOROLA/FETF, 120 SOUTH LASALLE STREET, SUITE 1600, CHICAGO, IL, 60603-3406, US

(73) Assignee: Motorola, Inc., Schaumburg, IL (US)

(21) Appl. No.: 12/270,544

(22) Filed: Nov. 13, 2008

Related U.S. Application Data
(62) Division of application No. 11/258,747, filed on Oct. 26, 2005.

(51) Int. Cl. H01L 21/66; H01L 21/302

(52) U.S. Cl. 438/16; 118/211; 118/712; 438/18; 257/E21.531

(57) ABSTRACT

A printing platform receives (102) (preferably in-line with a semiconductor device printing process (101)) a substrate having at least one semiconductor device printed thereon and further having a test structure printed thereon, which test structure comprises at least one printed semiconductor layer. These teachings then provide for the automatic testing (103) of the test structure with respect to at least one static (i.e., relatively unchanging) electrical characteristic metric. The static electrical characteristic metric (or metrics) of choice will likely vary with the application setting but can include, for example, a measure of electrical resistance, a measure of electrical reactance, and/or a measure of electrical continuity. Optionally (though preferably) the semiconductor device printing process itself is then adjusted (105) as a function, at least in part, of this metric.

### TECHNICAL FIELD

This invention relates generally to the printing of semiconductor devices.

### BACKGROUND

Methods and apparatus that use such techniques as vacuum deposition to form semiconductor-based devices of various kinds are well known. Such techniques serve well for many purposes and can achieve high reliability, small size, and relative economy when applied in high volume settings. Recently, other techniques are being explored to yield semiconductor-based devices. For example, organic or inorganic semiconductor materials can be provided as a functional ink and used in conjunction with various printing techniques to yield printed semiconductor devices.

Printed semiconductor devices, however, yield considerably different end results and make use of considerably different fabrication techniques than those skilled in the art of semiconductor manufacture are prone to expect. For example, both the materials employed and the deposition techniques utilized are also well outside the norm of prior art expectations. Consequently, in many cases, semiconductor device printing gives rise to challenges and difficulties that are without parallel in prior art practice.

For example, large-scale graphic-arts printing equipment typically requires numerous adjustments before one attains acceptable color matching, registration, and so forth. These adjustments are typically based upon a visual inspection of the printed work product by highly experienced press operators. Such visual testing can meet some of the needs of printing semiconductor devices but unfortunately cannot readily meet all testing needs. Since graphic art printing inherently yields a visual product, visual inspection has historically been adequate. This existing “infrastructure” and its corresponding paradigm is not sufficient for electronics printing, however, since critical attributes typically cannot be effectively inspected visually.

It is, of course, possible to electrically test a printed semiconductor device such as a transistor to ascertain its operability. Such testing, however, tends to be relatively time consuming. In particular, exercising a printed transistor in order to accomplish such testing can consume considerably more time than would ordinarily be available when used in-line with a modern high speed printing facility that may operate at upwards of 300 feet per minute. Also, this sort of device testing is often insufficient for process monitoring purposes.

### BRIEF DESCRIPTION OF THE DRAWINGS

The above needs are at least partially met through provision of the method and apparatus to facilitate testing of printed semiconductor devices described in the following detailed description, particularly when studied in conjunction with the drawings, wherein:

FIG. 1 comprises a flow diagram as configured in accordance with various embodiments of the invention;

FIG. 2 comprises a schematic block diagram as configured in accordance with various embodiments of the invention;

FIG. 3 comprises a top plan schematic view as configured in accordance with various embodiments of the invention;

FIG. 4 comprises a top plan view of a test structure as configured in accordance with various embodiments of the invention;

FIG. 5 comprises a top plan view of a test structure as configured in accordance with various embodiments of the invention;

FIG. 6 comprises a top plan view of a test structure as configured in accordance with various embodiments of the invention;

FIG. 7 comprises a top plan view of a test structure as configured in accordance with various embodiments of the invention;

FIG. 8 comprises a top plan view of a test structure as configured in accordance with various embodiments of the invention; and

FIG. 9 comprises a top plan view of a test structure as configured in accordance with various embodiments of the invention.

Skilled artisans will appreciate that elements in the figures are illustrated for simplicity and clarity and have not necessarily been drawn to scale. For example, the dimensions and/or relative positioning of some of the elements in the figures may be exaggerated relative to other elements to help to improve understanding of various embodiments of the present invention. Also, common but well-understood elements that are useful or necessary in a commercially feasible embodiment are often not depicted in order to facilitate a less obstructed view of these various embodiments of the present invention. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION

Generally speaking, pursuant to these various embodiments, one receives (preferably in-line with a semiconductor device printing process) a substrate having at least one semiconductor device printed thereon and further having a test structure printed thereon, which test structure comprises at least one printed semiconductor layer. These teachings then provide for the automatic testing of the test structure with respect to at least one static (i.e., relatively unchanging) electrical characteristic metric. The static electrical characteristic metric (or metrics) of choice will likely vary with the application setting but can include, for example, a measure of electrical resistance, a measure of electrical reactance, and/or a measure of electrical continuity. Optionally (though preferably) the semiconductor device printing process itself is then adjusted as a function, at least in part, of this metric.

Testing of the test structure can be carried out in any of a wide variety of ways. Both contact and non-contact testing operations can be employed as desired. If desired, a pogo pin assembly can be employed as a suitable testing platform.

So configured, the likely operational integrity of one or more printed semiconductor devices are readily tested via these test structures. It is not necessary (or even necessarily desirable) that these test structures themselves comprise viable operational devices in order to achieve these purposes. Testing can be accomplished at a rate of speed that will accommodate the real-time throughput of a typical printing line. This, in turn, permits a relatively high resolution view of the printed yield quality. The test structures themselves can occupy relatively small amounts of space and hence are not particularly wasteful of printing substrate space or printing materials.

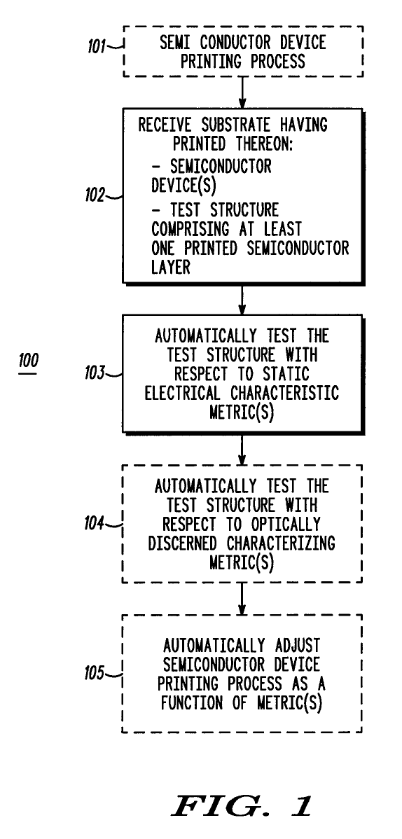

These and other benefits will become more evident to those skilled in the art upon making a thorough review and study of the following detailed description. Referring now to the drawings, and in particular to FIG. 1, an overall process 100 representative of these various teachings optionally but preferably works in conjunction with a semiconductor device printing process 101 (including either a contact printing process or a non-contact printing process). It may be helpful to the reader to first briefly describe certain aspects of a typical semiconductor device printing process.

Such a printing process usually uses a substrate that can comprise any suitable material including various rigid and non-rigid materials. In a preferred embodiment, the substrate comprises a flexible substrate comprised, for example, of polyester or paper. The substrate can be comprised of a single substantially amorphous material or can comprise, for example, a composite of differentiated materials (for example, a laminate construct). In a typical embodiment the substrate will comprise an electrical insulator though for some applications, designs, or purposes it may be desirable to utilize a material (or materials) that tend towards greater electrical conductivity.

Those skilled in the printing arts are familiar with both graphic inks and so-called functional inks (wherein “ink” is generally understood to comprise a suspension, solution, or dispersant that is presented as a liquid or paste, or a powder (such as a toner powder)). These functional inks are further comprised of metallic, organic, or inorganic materials having any of a variety of shapes (spherical, flakes, fibers, tubes) and sizes ranging, for example, from micron to nanometer. Functional inks find application, for example, in the manufacture of some membrane keypads. Though graphic inks can be employed as appropriate in combination with this process, these inks are more likely, in a preferred embodiment, to comprise a functional ink.

In a preferred approach, such inks are placed on the substrate by use of a corresponding printing technique. Those familiar with traditional semiconductor fabrication techniques such as vacuum deposition will know that the word “printing” is sometimes used loosely in those arts to refer to such techniques. As used herein, however, the word “printing” is used in a more mainstream and traditional sense and does not include such techniques as vacuum deposition that involve, for example, a state change of the transferred medium in order to effect the desired material placement. Accordingly, “printing” will be understood to include such techniques as screen printing, offset printing, gravure printing, xerographic printing, flexography printing, inkjetting, microdispensing, stamping, and the like. It will be understood that these teachings are compatible with the use of a plurality of such printing techniques during fabrication of a given element such as a semiconductor device. For example, it may be desirable to print a first device element (or portion of a device element) using a first ink and a first printing process and a second, different ink using a second, different print process for a different device element (or portion of the first device element).

For purposes of illustration and not by way of limitation, a semiconductor device such as a transistor can be formed using such materials and processes as follows. A gate can be printed on a substrate of choice using a conductive ink of choice (such as but not limited to a functional ink containing copper or silver, such as DuPont's Ag 5028 combined with 2% 3610 thinner). Pursuant to one approach, air is blown over the printed surface after a delay of, for example, four seconds. An appropriate solvent can then be used to further form, define, or otherwise remove excess material from the substrate. Thermal curing at around 120 degrees Centigrade for 30 minutes can then be employed to assure that the printed gate will suitably adhere to the substrate.

A dielectric layer may then be printed over at least a substantial portion of the above-mentioned gate using, for example, an appropriate epoxy-based functional ink (such as, for example, DuPont's 5018A ultraviolet curable material). By one approach, the dielectric layer comprises a laminate of two or more layers. When so fabricated, each layer can be processed under an ultraviolet lamp before applying a next layer.

Additional electrodes are then again printed and cured using, for example, a copper or silver-based electrically conductive functional ink (such as, for example, DuPont's Ag 5028 with 2% 3610 thinner). These additional electrodes can comprise, for example, a source electrode and a drain electrode. A semiconductor material ink, such as but not limited to an organic or inorganic semiconductor material ink, is then printed to provide an area of semiconductor material that bridges a gap between the source electrode and the drain electrode.

With continued reference to FIG. 1, this process 100 then provides for receiving 102 a substrate having at least one semiconductor device printed thereon and further having a test structure printed thereon. In a preferred embodiment, this test structure comprises at least one printed semiconductor layer in order to facilitate testing of the semiconductor material content of the printing process. (In a preferred embodiment, there may be many such test structures. In many cases it will not be necessary or even helpful to include semiconductor material with each such test structure. For example, and as will be exemplified in more detail below, no semiconductor material may be needed when providing a test structure that will serve to facilitate testing continuity as between various non-semiconductor material layers.)

As noted above, the aforementioned substrate may comprise any suitable material such as, but not limited to, a substantially paper-like substrate, a plastic substrate, and so forth. In a typical embodiment the substrate will often comprise a plurality of printed semiconductor devices. Similarly, the test structure (or test structures) will usually likely comprise at least one electrical conductor layer and possibly at least one dielectric layer as well to facilitate testing of these layers. In a typical embodiment, of course, this substrate is so received in-line from the previously mentioned upstream semiconductor printing process 101. In a preferred approach this occurs substantially in real time with the cycle time of the printing process 101 itself.

This process 100 then provides for automatically testing 103 the test structure (or test structures) with respect to at least one static electrical characteristic metric. This static electrical characteristic metric can vary with the needs of a given application setting but may comprise, for example, one or more of a measure of electrical resistance, a measure of electrical reactance, and/or a measure of electrical continuity, to name a few. The testing itself can be accomplished using any presently known or hereafter-developed technique. For example, in some cases it may be appropriate to use at least one non-contact sensor (such as a capacitive sensor) to test the test structure with respect to the at least one static electrical characteristic metric.

When using contact-based sensing, and pursuant to a preferred though optional approach, the testing step can comprise use of a pogo pin assembly as is known in the art. In this particular embodiment, however, the pogo pin assembly may preferably generally comprise a rotating cylinder having pogo pins disposed thereon and extending outwardly therefrom. By one approach the pogo pin assembly could be essentially self-contained and have on-board wireless communications capability to permit transfer of its accumulated test information. A pogo pin assembly should effectively operate in a relatively high-speed context and is well-suited to match and accommodate the cycle time requirements that typify an in-line semiconductor device printing process as contemplated herein.

So configured, one or more relatively simple test structures (typically likely located and printed relatively proximal to an active circuit area) are provided and tested via use of relatively simple electrical measurements (such as, but not limited to, resistance and capacitance). As these measurements are in turn dependent to a considerable degree on layer thickness, material composition, registration accuracy, and so forth (i.e., various printing process attributes), these simple, rapidly-taken measurements provide useful information regarding the present quality of the upstream printing process.

If desired, such electrical testing can be supplemented by automatically testing 104 the test structure with respect to at least one optically discerned characterizing metric. For example, ink density and/or layer-to-layer registration may be measurable at least to some degree via such testing. As optical testing is a relatively well-understood practice, for the sake of brevity no further elaboration regarding such testing will be provided here.

The above-described process 100 will aid in ascertaining the present printing quality being yielded by a given semiconductor device printing process. Such information can then be employed to inform the modification and adjustment of that printing process to thereby improve that quality and thereby increase the effective yield thereof. In an optional but preferred process, such adjustment occurs in a dynamic fashion. More particularly, this process 100 can optionally accommodate automatically adjusting 105 the semiconductor device printing process 101 as a function, at least in part, of the at least one static electrical characteristic metric. For example, upon determining through an electrical resistance test that the semiconductor layer is misaligned with respect to a conductive material layer, the printing process can be automatically adjusted to seek to improve the layer-to-layer registration between such layers.

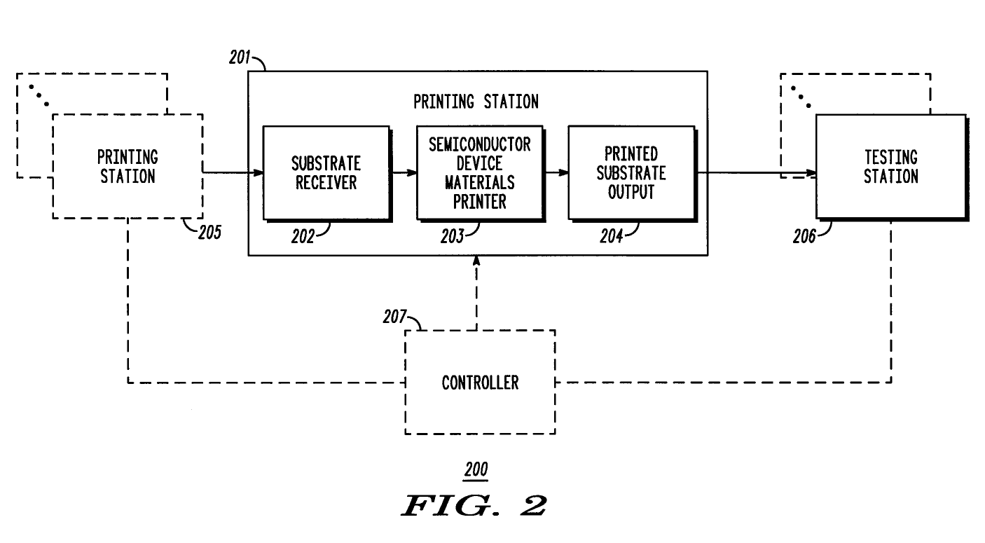

Those skilled in the art will appreciate that the above-described processes are readily enabled using any of a wide variety of available and/or readily configured platforms, including partially or wholly programmable platforms as are known in the art or dedicated purpose platforms as may be desired for some applications. Referring now to FIG. 2, an illustrative approach to such a platform will now be provided.

The illustrated embodiment presents a semiconductor device printing platform 200 that comprises, at least in part, at least one printing station 201 and at least one testing station 206. The printing station 201 preferably comprises a substrate receiver 202, a semiconductor device materials printer 203, and a printed substrate output 204. The substrate receiver 202 serves to receive a printing substrate as provided by an upstream source. For example, one or more additional printing stations 205 may positioned upstream of the printing station 201 being discussed and this printing station(s) may be providing a printing substrate that already has one or more device elements and/or test structure elements printed thereon. Various ways and techniques exist for moving a substrate from one printing platform to another in an in-line process and no doubt other approaches will be developed in the future. This being so and further because these teachings are not particularly sensitive to the selection of any particular substrate movement approach, for the sake of brevity additional detail regarding such points will not be provided here.

In a similar manner the printed substrate output 204 serves to provide printed substrates to a downstream platform of choice. As illustrated, the printed substrate output 204 provides the resultant substrate to testing station 206 but, if desired, there may be one or more intervening printing stations and/or other platforms offering a particular functionality of choice.

The semiconductor device materials printer 203 serves, in this embodiment, to print semiconductor material at least on a test structure. In a preferred approach this semiconductor device materials printer 203 also prints semiconductor material on one or more printed semiconductor devices to thereby facilitate and contribute to the manufacture of operating printed semiconductor devices. As noted above, this may comprise use of a contact printer and/or a non-contact printer depending upon the nature of the functional inks being employed and/or the desires or requirements of the operator.

So configured and arranged, the printing station 201 can print both functional semiconductor devices and one or more test structures comprising semiconductor material (or materials). Referring momentarily to FIG. 3, a corresponding printing substrate 300 of choice may have one semiconductor device 301 or more 302 and one test structure 303 or more 304 printed thereon. In some cases it may be appropriate to provide such test structures in relatively close proximity to a given one of the semiconductor devices (to aid in accounting, for example, for highly local phenomena and characteristics). Also in some cases it may be appropriate to provide a discrete test structure in conjunction with each provided semiconductor device (though in other cases it may be satisfactory to provide a few, or greater, number of test structures as compared to semiconductor devices). Other possibilities exist as well. For example, it would be possible to print multiple test structures for a given semiconductor device. In such a case, it would then be possible to array the test structures in a given pattern near, or around, the semiconductor device. Those skilled in graphic art will also understand that the printing substrate may comprise a so-called web rather than individual discrete sheets. When using a web it may be helpful to place at least one test structure approximately every 6 inches or so.

Referring again to FIG. 2, the testing station 206 will preferably have an input to receive printed substrates from the printing station 201 and is configured and arranged to automatically test the test structure with respect to at least one predetermined static electrical characteristic metric of choice and possibly a plurality of such metrics. Various such metrics may be useful in a given application setting. Potentially useful metrics include, but are not limited to, a measure of electrical resistance (which can serve, for example, to effectively measure the thickness of a semiconductor layer), a measure of electrical reactance (such as capacitance or inductance), and/or a measure of electrical continuity (where, of course, continuity might be viewed as a subset of resistance but where continuity typically comprises a yes/no kind of inquiry whereas resistance more typically yields a relative value regarding a particular amount of resistance).

As noted above such testing can be accomplished in any of a wide variety of presently known or likely hereafter-developed ways. This includes, but is not limited to, non-contact testing using non-contact sensors and contact testing using, for example, a pogo pin assembly as mentioned above.

So configured the testing station 206 is readily able to test the test structures as are applied to a printing substrate by the printing station 201 noted and/or by this printing station 201 in combination with one or more additional printing stations 205. In an optional though preferred approach, the developed testing metrics are provided to a controller 207 that operably couples to one or more of the printing stations and that is configured and arranged to automatically adjust one or more such printing station as a function, at least in part, of the developed testing metric. Such a controller can be configured to operate in a largely or wholly autonomous manner or can serve as an advisory vehicle to better inform the decisions and actions of printing station operating personnel with such control strategies being generally understood in the art.

As alluded to earlier, these teachings are compatible for use with a wide variety of test structures. To assist the reader in appreciating the scope and breadth of such compatibility and applicability, and without any intent to make an exhaustive presentation in this regard, a number of illustrative test structures will now be described.

FIG. 4 presents a test structure 400 comprising a first printed metal layer. Such a test structure can serve, for example, to quickly test continuity between various test points to thereby gain some understanding of printing quality as pertains to this particular layer and printing process.

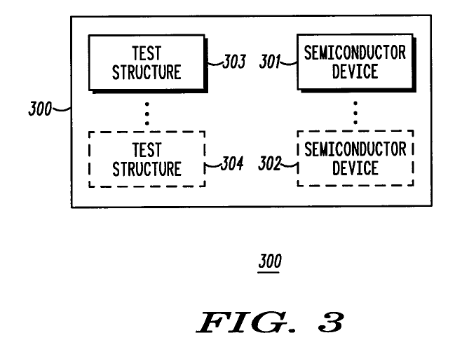

FIG. 5 presents a test structure 500 comprising a number of printed conductive fingers 501 formed during the printing of a first conductive layer and a bridge section 502 formed during the printing of a second conductive layer. This test structure 500 would be useful, for example, to test layer-to-layer registration as between these two printing layers. For example, when mis-registration occurs, the bridge section 502 may fail to contact at least one of the conductive fingers 501. This, in turn, will result in an electrical discontinuity that can be quickly electrically ascertained. It may further be noted that an electrical test of this sort may reveal discontinuities in instances where a visual examination might fail to discern the discontinuity.

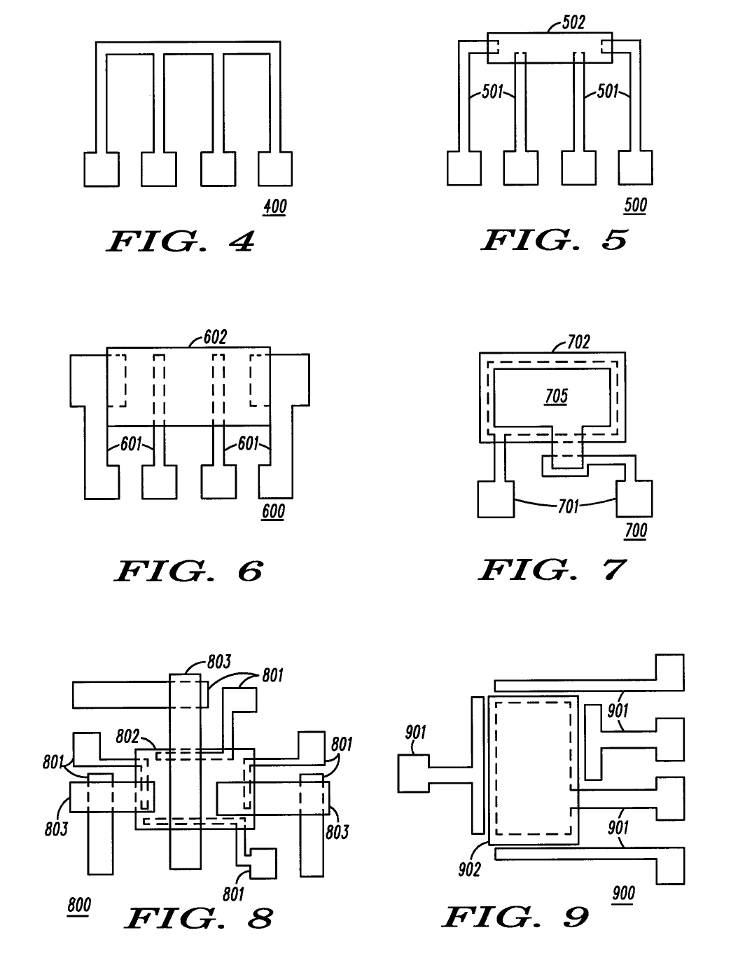

FIG. 6 presents a test structure 600 comprising a number of printed conductive fingers 601 formed during the printing of a first conductive layer and an overlying layer of printed semiconductor material 602. Those skilled in the art will recognize that such a test structure does not comprise, and will not operate as, a standard semiconductor device such as a transistor or diode. Those skilled in the art will also now understand, however, that simple static electrical measurements, such as a measure of resistivity or reactance, can be employed in such a setting to provide corresponding measurements that, when compared to corresponding calibrated values, can provide useful information regarding, for example, layer-to-layer registration as well as thickness and/or purity of the semiconductor material 602 itself.

FIG. 7 presents a test structure 700 comprising a number of printed conductive fingers 701 formed during the printing of a first conductive layer, an overlying layer of conductive material 703 formed during the printing of a subsequent conductive layer, and an intervening layer of printed dielectric material 702. So configured, for example, an electrical measurement taken across the two depicted first layer conductive fingers 701 can quickly provide useful test information regarding, for example, the thickness, quality, and registration of the dielectric material 702.

FIG. 8 presents a test structure 800 comprising a number of printed conductive fingers 801 formed during the printing of a first conductive layer, an overlying number of additional conductive fingers 803 formed during the printing of a subsequent conductive layer, and an intervening layer of printed dielectric material 802. So configured, various tests can be conducted to determine, for example, registration issues with respect to the dielectric and conductive layers. Those skilled in the art will further recognize and see that various of such measurements could be employed to not only detect mis-registration but to also detect a direction in which the mis-registration tends. For example, the various test point opportunities provided in this test structure 800 will support a determination as to whether mis-registration, when present, is vertically or horizontally inclined and whether such inclination is towards the relative left, right, up, or down (presuming the orientation suggested by FIG. 8).

And FIG. 9 presents a test structure 900 comprising a number of printed conductive fingers 901 formed during the printing of a first conductive layer and an overlying layer of printed semiconductor material 902. In this example at least some of the conductive fingers 901 are positioned to extend closely along the intended periphery of the semiconductor material 902. When properly printed, most of these conductive fingers 901, however, will not contact the semiconductor material. A simple electrical test regarding, for example, resistance can be employed to detect when mis-registration occurs and to also indicate, again, in which direction the mis-registration has occurred to thereby better facilitate its correction.

Those skilled in the art will recognize that a wide variety of modifications, alterations, and combinations can be made with respect to the above described embodiments without departing from the spirit and scope of the invention, and that such modifications, alterations, and combinations are to be viewed as being within the ambit of the inventive concept.

1-12. (canceled)

13. A semiconductor device printing platform comprising:
at least one printing station having a substrate receiver, a semiconductor device materials printer, and a printed substrate output, wherein the semiconductor device materials printer is configured and arranged to print both a functional semiconductor device and a test structure, which test structure comprises at least one printed semiconductor layer;
at least one testing station having an input to receive printed substrates from the printing station and being configured and arranged to automatically test the test structure with respect to at least one static electrical characteristic metric.

14. The semiconductor device printing platform of claim 13 wherein the semiconductor device materials printer comprises at least one of a contact printer and a non-contact printer.

15. The semiconductor device printing platform of claim 13 wherein the printed substrates comprises at least one of:
a substantially paper-like substrate;
a plastic substrate.

16. The semiconductor device printing platform of claim 13 wherein the at least one static electric characteristic metric comprises at least one of:
a measure of electrical resistance;
a measure of electrical reactance;
a measure of electrical continuity.

17. The semiconductor device printing platform of claim 13 further comprising a controller that is operably coupled to the at least one printing station and the at least one testing station and being configured and arranged to automatically adjust the at least one printing station as a function, at least in part, of the at least one static electrical characteristic metric.

18. The semiconductor device printing platform of claim 13 wherein the test structure comprises a pogo pin assembly.

19. The semiconductor device printing platform of claim 18 wherein the pogo pin assembly further comprises a rotating cylinder having pogo pins disposed thereon.

20. The semiconductor device printing platform of claim 13 wherein the test structure comprises at least one non-contact sensor.
